(19) United States
(12) Patent Application Publication
(10) Pub. No.: US 2026/0179882 A1
(43) Pub. Date: Jun. 25, 2026

(54) PROCESSING APPARATUS AND PROCESSING METHOD

(71) Applicant: Tokyo Electron Limited, Tokyo (JP)

(72) Inventors: Takuya SUZUKI, Miyagi (JP); Yuji AOTA, Miyagi (JP); Hiroto ITO, Miyagi (JP); Koji MARUYAMA, Miyagi (JP)

(73) Assignee: Tokyo Electron Limited, Tokyo (JP)

(21) Appl. No.: 19/539,554

(22) Filed: Feb. 13, 2026

Related U.S. Application Data
(63) Continuation of application No. PCT/JP2024/027460, filed on Aug. 1, 2024.

(30) Foreign Application Priority Data
Aug. 14, 2023 (JP) 2023-131806

(51) Int. Cl. H01J 37/32

(52) U.S. Cl. CPC H01J 37/3244

(57) ABSTRACT

A processing apparatus includes a first member, a second member, an ERG (Electro-Rheological Gel) sheet disposed between the first member and the second member, and control circuitry. The ERG sheet includes an ERG layer, a plurality of electrode pairs each having two electrodes, and a substrate on which the plurality of electrode pairs are disposed. The control circuitry is configured to control the thermal conductivity of the ERG layer, for each of the plurality of electrode pairs, by independently controlling voltages applied to each of the plurality of electrode pairs such that a temperature distribution of the first member or the second member becomes a predetermined temperature distribution due to heat exchange between the first member and the second member.

### CROSS-REFERENCE TO RELATED APPLICATIONS

This application is a continuation of International Application No. PCT/JP2024/027460, filed on Aug. 1, 2024 which claims the benefit of priority of the prior Japanese Patent Application No. 2023-131806, filed on Aug. 14, 2023, the entire contents of each are incorporated herein by reference.

### FIELD

Various aspects and embodiments of the present disclosure relate to a processing apparatus and a processing method.

### BACKGROUND

Japanese Patent No. 5987699 describes an electro-rheological gel (hereinafter referred to as “ER gel”) whose surface adhesiveness changes by applying a voltage. The ER gel can change a fixing force by voltage control.

### SUMMARY

A processing apparatus according to the present disclosure includes a first member, a second member, an ERG (Electro-Rheological Gel) sheet disposed between the first member and the second member, and control circuitry. The ERG sheet includes an ERG layer, a plurality of electrode pairs each having two electrodes, and a substrate on which the plurality of electrode pairs are disposed. The control circuitry independently is configured to control the thermal conductivity of the ERG layer, for in the vicinity of each of the plurality of electrode pairs, by independently controlling voltages applied to each of the plurality of electrode pairs such that a temperature distribution of the first member or the second member becomes a predetermined temperature distribution due to heat exchange between the first member and the second member.

### BRIEF DESCRIPTION OF DRAWINGS

FIG. 1 is a schematic diagram showing an example of a plasma processing apparatus;

FIG. 2 is an enlarged cross-sectional view showing an example of a detailed structure near an outer periphery of a shower head;

FIG. 3 is a cross-sectional view showing an example of a structure of an ERG sheet;

FIG. 4 is a plan view showing an example of arrangement of flow paths of a cooling plate;

FIG. 5 is a plan view showing an example of arrangement of electrode pairs;

FIG. 6 is a flowchart showing an example of a processing method;

FIG. 7 is a cross-sectional view showing another example of a structure of an ERG sheet;

FIG. 8 is a cross-sectional view showing another example of a structure of an ERG sheet;

FIG. 9 is a cross-sectional view showing another example of a structure of an ERG sheet;

FIG. 10 is an enlarged cross-sectional view showing another example of a detailed structure near an outer periphery of a shower head; and

FIG. 11 is a flowchart showing another example of a processing method.

### DESCRIPTION OF EMBODIMENTS

The present disclosure provides a processing apparatus and a processing method capable of accurately controlling a temperature distribution of a member.

Hereinafter, embodiments of a processing apparatus and a processing method will be described in detail with reference to the drawings. The processing apparatus and the processing method disclosed herein are not limited to the following embodiments.

When two members are in contact with each other, a heat transfer coefficient may differ for each location on a contact surface depending on a state of the contact surface. In addition, the state of the contact surface may change due to temperature changes of the members, changes over time, or the like, and the heat transfer coefficient may further change. When heat is transferred between two members via a contact surface, if the heat transfer coefficient differs for each location, it may be difficult to control a temperature distribution of the other member to a desired temperature distribution when controlling the temperature of the other member by controlling the temperature of one member.

Therefore, the present disclosure provides a technology capable of accurately controlling a temperature distribution of a member.

### Configuration of Plasma Processing Apparatus 1

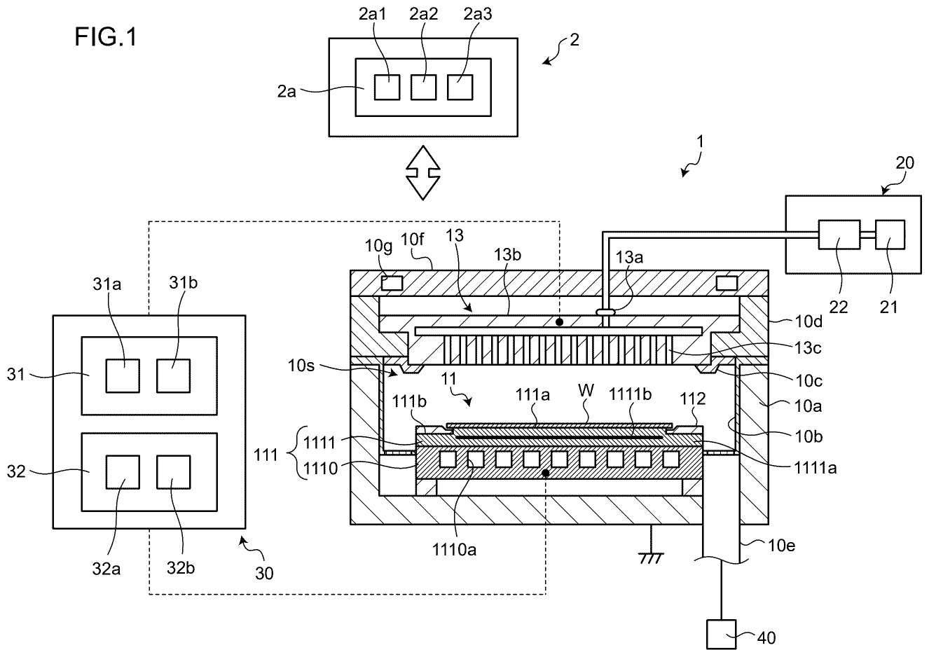

Hereinafter, a configuration example of a plasma processing system will be described. FIG. 1 is a diagram for explaining a configuration example of a capacitively coupled plasma processing apparatus 1. The plasma processing apparatus 1 is an example of a processing apparatus.

The plasma processing system includes a capacitively coupled plasma processing apparatus 1 and a control unit 2. The capacitively coupled plasma processing apparatus 1 includes a plasma processing chamber 10, a gas supply unit 20, a power supply 30, and an exhaust system 40. The plasma processing chamber 10 is an example of a processing container. The plasma processing apparatus 1 includes a substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one embodiment, the shower head 13 constitutes at least a part of a ceiling of the plasma processing chamber 10. The plasma processing chamber 10 has a plasma processing space 10s defined by the shower head 13, a side wall 10a of the plasma processing chamber 10, and the substrate support 11. The plasma processing chamber 10 has at least one gas supply port for supplying at least one processing gas to the plasma processing space 10s and at least one gas exhaust port for exhausting gas from the plasma processing space. The plasma processing chamber 10 is grounded. The shower head 13 and the substrate support 11 are electrically insulated from a housing of the plasma processing chamber 10.

The substrate support 11 includes a main body portion 111 and a ring assembly 112. The main body portion 111 has a central region 111a for supporting a substrate W and an annular region 111b for supporting the ring assembly 112. A wafer is an example of the substrate W. The annular region 111b of the main body portion 111 surrounds the central region 111a of the main body portion 111 in plan view. The substrate W is disposed on the central region 111a of the main body portion 111, and the ring assembly 112 is disposed on the annular region 111b of the main body portion 111 so as to surround the substrate W on the central region 111a of the main body portion 111. Therefore, the central region 111a is also referred to as a substrate supporting surface for supporting the substrate W, and the annular region 111b is also referred to as a ring supporting surface for supporting the ring assembly 112.

In one embodiment, the main body portion 111 includes a base 1110 and an electrostatic chuck 1111. The base 1110 includes a conductive member. The conductive member of the base 1110 can function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has a central region 111a. In one embodiment, the ceramic member 1111a also has an annular region 111b. Note that other members surrounding the electrostatic chuck 1111, such as an annular electrostatic chuck or an annular insulating member, may have the annular region 111b. In this case, the ring assembly 112 may be disposed on the annular electrostatic chuck or the annular insulating member, or may be disposed on both the electrostatic chuck 1111 and the annular insulating member. In addition, at least one RF (Radio Frequency)/DC (Direct Current) electrode coupled to an RF power supply 31 and/or a DC power supply 32 described later may be disposed in the ceramic member 1111a. In this case, the at least one RF/DC electrode functions as a lower electrode. When a bias RF signal and/or a DC signal described later is supplied to the at least one RF/DC electrode, the RF/DC electrode is also referred to as a bias electrode. Note that the conductive member of the base 1110 and the at least one RF/DC electrode may function as a plurality of lower electrodes. In addition, the electrostatic electrode 1111b may function as a lower electrode. Therefore, the substrate support 11 includes at least one lower electrode.

The ring assembly 112 includes one or more annular members. In one embodiment, the one or more annular members include one or more edge rings and at least one cover ring. The edge ring is formed of a conductive material or an insulating material, and the cover ring is formed of an insulating material.

In addition, the substrate support 11 may include a temperature control module configured to adjust at least one of the electrostatic chuck 1111, the ring assembly 112, and the substrate to a target temperature. The temperature control module may include a heater, a heat transfer fluid, a flow path 1110a, or a combination thereof. A heat transfer fluid such as brine or gas flows through the flow path 1110a. In one embodiment, the flow path 1110a is formed in the base 1110, and one or more heaters are disposed in the ceramic member 1111a of the electrostatic chuck 1111. In addition, the substrate support 11 may include a heat transfer gas supply unit configured to supply a heat transfer gas to a gap between a back surface of the substrate W and the central region 111a.

The shower head 13 is provided at an upper part of the plasma processing chamber 10. The shower head 13 is supported by a support member 10d provided on the side wall 10a of the plasma processing chamber 10. A cooling plate 10f is provided above the shower head 13. A flow path 10g through which a heat transfer fluid such as brine or gas flows is formed in the cooling plate 10f. A deposition shield 10b and a member 10c are provided below the support member 10d. The deposition shield 10b covers the side wall 10a and suppresses reaction by-products (so-called deposition) generated by processing in the plasma processing space 10s from adhering to the side wall 10a. The member 10c is formed of a conductive member such as silicon, and is disposed on a lower surface of the shower head 13 along an outer periphery of the shower head 13. The member 10c is grounded. The member 10c and the deposition shield 10b are heated by plasma generated in the plasma processing space 10s.

The shower head 13 is configured to introduce at least one processing gas from the gas supply unit 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. In addition, the shower head 13 includes at least one upper electrode. Note that the gas introduction unit may include, in addition to the shower head 13, one or more side gas injectors (SGI) attached to one or more openings formed in the side wall 10a.

The gas supply unit 20 may include at least one gas source 21 and at least one flow rate controller 22. In one embodiment, the gas supply unit 20 is configured to supply at least one processing gas from a corresponding gas source 21 to the shower head 13 via a corresponding flow rate controller 22. Each flow rate controller 22 may include, for example, a mass flow controller or a pressure-controlled flow rate controller. Furthermore, the gas supply unit 20 may include one or more flow rate modulation devices that modulate or pulse a flow rate of the at least one processing gas.

The power supply 30 includes an RF power supply 31 coupled to the plasma processing chamber 10 via at least one impedance matching circuit. The RF power supply 31 is configured to supply at least one RF signal (RF power) to at least one lower electrode and/or at least one upper electrode. As a result, plasma is formed from the at least one processing gas supplied to the plasma processing space 10s. Therefore, the RF power supply 31 can function as at least a part of a plasma generation unit configured to generate plasma from one or more processing gases in the plasma processing chamber 10. In addition, by supplying a bias RF signal to the at least one lower electrode, a bias potential is generated on the substrate W, and an ion component in the formed plasma can be attracted to the substrate W.

In one embodiment, the RF power supply 31 includes a first RF generation unit 31a and a second RF generation unit 31b. The first RF generation unit 31a is coupled to at least one lower electrode and/or at least one upper electrode via at least one impedance matching circuit, and is configured to generate a source RF signal (source RF power) for plasma generation. In one embodiment, the source RF signal has a frequency within a range of 10 MHz to 150 MHz. In one embodiment, the first RF generation unit 31a may be configured to generate a plurality of source RF signals having different frequencies. The generated one or more source RF signals are supplied to the at least one lower electrode and/or the at least one upper electrode.

The second RF generation unit 31b is coupled to at least one lower electrode via at least one impedance matching circuit, and is configured to generate a bias RF signal (bias RF power). The frequency of the bias RF signal may be the same as or different from the frequency of the source RF signal. In one embodiment, the bias RF signal has a frequency lower than the frequency of the source RF signal. In one embodiment, the bias RF signal has a frequency within a range of 100 kHz to 60 MHz. In one embodiment, the second RF generation unit 31b may be configured to generate a plurality of bias RF signals having different frequencies. The generated one or more bias RF signals are supplied to the at least one lower electrode. In addition, in various embodiments, at least one of the source RF signal and the bias RF signal may be pulsed.

In addition, the power supply 30 may include a DC power supply 32 coupled to the plasma processing chamber 10. The DC power supply 32 includes a first DC generation unit 32a and a second DC generation unit 32b. In one embodiment, the first DC generation unit 32a is connected to at least one lower electrode and is configured to generate a first DC signal. The generated first bias DC signal is applied to the at least one lower electrode. In one embodiment, the second DC generation unit 32b is connected to at least one upper electrode and is configured to generate a second DC signal. The generated second DC signal is applied to the at least one upper electrode.

In various embodiments, at least one of the first and second DC signals may be pulsed. In this case, a sequence of voltage pulses is applied to the at least one lower electrode and/or the at least one upper electrode. The voltage pulse may have a rectangular, trapezoidal, triangular, or a combination of these pulse waveforms. In one embodiment, a waveform generation unit for generating a sequence of voltage pulses from a DC signal is connected between the first DC generation unit 32a and the at least one lower electrode. Therefore, the first DC generation unit 32a and the waveform generation unit constitute a voltage pulse generation unit. When the second DC generation unit 32b and the waveform generation unit constitute a voltage pulse generation unit, the voltage pulse generation unit is connected to the at least one upper electrode. The voltage pulse may have a positive polarity or may have a negative polarity. In addition, the sequence of voltage pulses may include one or more positive polarity voltage pulses and one or more negative polarity voltage pulses within one period. Note that the first and second DC generation units 32a and 32b may be provided in addition to the RF power supply 31, or the first DC generation unit 32a may be provided in place of the second RF generation unit 31b.

The exhaust system 40 may be connected to, for example, a gas exhaust port 10e provided at a bottom of the plasma processing chamber 10. The exhaust system 40 may include a pressure adjustment valve and a vacuum pump. The pressure in the plasma processing space 10s is adjusted by the pressure adjustment valve. The vacuum pump may include a turbo molecular pump, a dry pump, or a combination thereof.

The control unit 2 processes computer-executable instructions that cause the plasma processing apparatus 1 to execute various processes described in the present disclosure. The control unit 2 may be configured to control each element of the plasma processing apparatus 1 to execute various processes described herein. In one embodiment, a part or all of the control unit 2 may be included in the plasma processing apparatus 1. The control unit 2 may include a processing unit 2a1, a storage unit 2a2, and a communication interface 2a3. The control unit 2 is realized by, for example, a computer 2a. The processing unit 2a1 may be configured to perform various control operations by reading a program from the storage unit 2a2 and executing the read program. This program may be stored in the storage unit 2a2 in advance, or may be acquired via a medium. The acquired program is stored in the storage unit 2a2, read from the storage unit 2a2 by the processing unit 2a1, and executed. The medium may be various storage media readable by the computer 2a, or may be a communication line connected to the communication interface 2a3. The processing unit 2a1 may be a CPU (Central Processing Unit). The storage unit 2a2 may include a RAM (Random Access Memory), a ROM (Read Only Memory), an HDD (Hard Disk Drive), an SSD (Solid State Drive), or a combination thereof. The communication interface 2a3 may communicate with the plasma processing apparatus 1 via a communication line such as a LAN (Local Area Network). The functionality of the control unit 2 may be implemented using circuitry or processing circuitry, including general purpose processors, special purpose processors, integrated circuits, ASICs (“Application Specific Integrated Circuits”), FPGAs (“Field-Programmable Gate Arrays”), conventional circuitry and/or combinations thereof which are programmed using one or more programs stored in one or more memories, or otherwise configured to perform the disclosed functionality. Processors and controllers are considered processing circuitry or circuitry as they include transistors and other circuitry therein. As used herein, the circuitry, units, or means refer to hardware that is configured or programmed to perform the recited functionality. The hardware may be any hardware disclosed herein which is programmed or configured to carry out the recited functionality.

### Structure of Upper Part of Plasma Processing Chamber 10

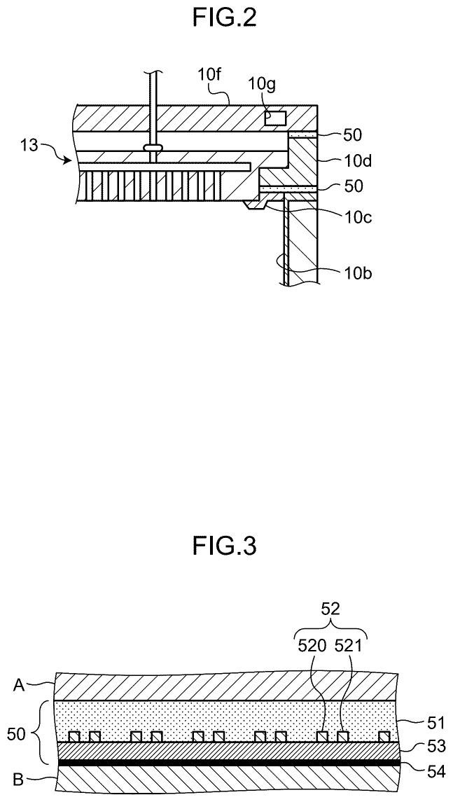

FIG. 2 is an enlarged cross-sectional view showing an example of a detailed structure near an outer periphery of the shower head 13. An ERG sheet 50 is disposed between the cooling plate 10f and the support member 10d, between the support member 10d and the deposition shield 10b, and between the support member 10d and the member 10c. The cooling plate 10f performs heat exchange with the support member 10d via the ERG sheet 50 to cool the support member 10d. The support member 10d performs heat exchange with the deposition shield 10b and the member 10c via the ERG sheet 50 to cool the deposition shield 10b and the member 10c. In the relationship between the cooling plate 10f and the support member 10d, the cooling plate 10f is an example of a first member, and the support member 10d is an example of a second member. In addition, in the relationship between the support member 10d and the deposition shield 10b and the member 10c, the support member 10d is an example of a first member, and the deposition shield 10b and the member 10c are examples of a second member.

The ERG sheet 50 has, for example, a structure as shown in FIG. 3. FIG. 3 is a cross-sectional view showing an example of a structure of the ERG sheet 50. In FIG. 3, the ERG sheet 50 is disposed between a member A and a member B. The member A and the member B may be, for example, the cooling plate 10f and the support member 10d, the support member 10d and the deposition shield 10b, or the support member 10d and the member 10c. Note that a recess shallower than the thickness of the ERG sheet 50 may be formed in the member A or the member B, and the ERG sheet 50 may be disposed in the recess. This can facilitate positioning of the ERG sheet 50.

The ERG sheet 50 has an ER (Electro-Rheological) gel 51, a plurality of electrode pairs 52, and a substrate 53. The ER gel 51 is an example of an ERG layer. Each electrode pair 52 has an electrode 520 and an electrode 521, and is disposed on a surface of the substrate 53. In the example of FIG. 3, the electrode pair 52 and the ER gel 51 are disposed on one surface of the substrate 53, the ER gel 51 in the ERG sheet 50 is disposed on the member A side, and the substrate 53 is disposed on the member B side.

A voltage controlled by the control unit 2 is applied between the electrode 520 and the electrode 521. The thermal conductivity of the ER gel 51 in the vicinity of the electrode 520 and the electrode 521 changes according to the magnitude of the voltage applied between the electrode 520 and the electrode 521. The magnitude of the voltage applied between the electrode 520 and the electrode 521 is controlled independently of each other in each electrode pair 52. By controlling the voltage applied to each electrode pair 52, a heat transfer coefficient between the member A and the member B via the ER gel 51 in the vicinity of the electrode pair 52 can be individually controlled.

Between the substrate 53 and the member B, a thermally conductive sheet 54 having high thermal conductivity, electrical conductivity and elasticity is disposed. Examples of such a thermally conductive sheet 54 include a conductive metal foil tape in which metal particles such as gold, silver, copper, and aluminum are dispersed in an adhesive resin such as epoxy, and the like. Note that, instead of the thermally conductive sheet 54, for example, a paste-like metal adhesive such as gold, silver, copper, or aluminum, heat-resistant rubber (based on organic polymers such as natural rubber or synthetic rubber), silicone rubber, an adhesive using silicon, or the like may be disposed.

For the substrate 53, an insulating material such as a resin film such as polyimide or polyethylene terephthalate, glass, a resin plate such as epoxy resin or phenol resin, or a ceramic such as alumina may be used. The substrate 53 is preferably formed of a material having high thermal conductivity.

The ER gel 51 contains a gel and fine particles. Examples of the gel include silicone gel, silicone oil, mineral oil, and the like. The silicone gel is, for example, a gel formed by mixing two gelling agents and a catalyst with an ER fluid and heat-treating the mixture.

Examples of the fine particles include inorganic-organic composite fine particles having an acrylic polymer as a core and coated with tin oxide, silica particles, polymer electrolyte particles, conductive polymer particles, those having a surface coated with conductive polymer particles, sodium polymethacrylate particles, lithium polymethacrylate, cellulose, zeolite, carbon, polyaniline, and the like.

In addition, by using particles such as plate-like alumina, metal silicon, and SiC as the fine particles, the thermal conductivity of the ER gel 51 can be improved. In addition, a three-dimensional fine structure formed by a 3D printer, photolithography, or the like may be added to the ER gel 51.

Here, when the two members A and B are in contact with each other, the heat transfer coefficient may differ for each location on the contact surface depending on the state of the contact surface. In addition, the state of the contact surface may change due to temperature changes of the members A and B, changes over time, or the like, and the heat transfer coefficient may further change. Furthermore, the state of the contact surface and changes in the state of the contact surface may differ from apparatus to apparatus. When heat is transferred between the two members A and B via a contact surface, if the heat transfer coefficient differs for each location, it may be difficult to control a temperature distribution of the other member to a desired temperature distribution when controlling the temperature of the other member by controlling the temperature of one member.

Therefore, in the present embodiment, as shown in FIG. 3, for example, a gel-like ER gel 51 is disposed between the member A and the substrate 53, and a thermally conductive sheet 54 having elasticity is disposed between the substrate 53 and the member B. This can improve adhesion between the member A and the ER gel 51 and between the substrate 53 and the member B. This can suppress unevenness of heat transfer between the member A and the member B via the ERG sheet 50. Therefore, when controlling the temperature of the other by controlling the temperature of one of the members A and B, the temperature distribution of the other can be controlled to a desired temperature distribution.

In addition, the gel-like ER gel 51 is disposed between the member A and the substrate 53, and the thermally conductive sheet 54 having elasticity is disposed between the substrate 53 and the member B. As a result, even if the members A and B are deformed due to temperature changes of the members A and B, changes over time, or the like, the ER gel 51 and the thermally conductive sheet 54 are deformed following the deformation of the members A and B. This can maintain adhesion between the member A and the ER gel 51 and between the substrate 53 and the member B even when the members A and B are deformed due to temperature changes of the members A and B, changes over time, or the like.

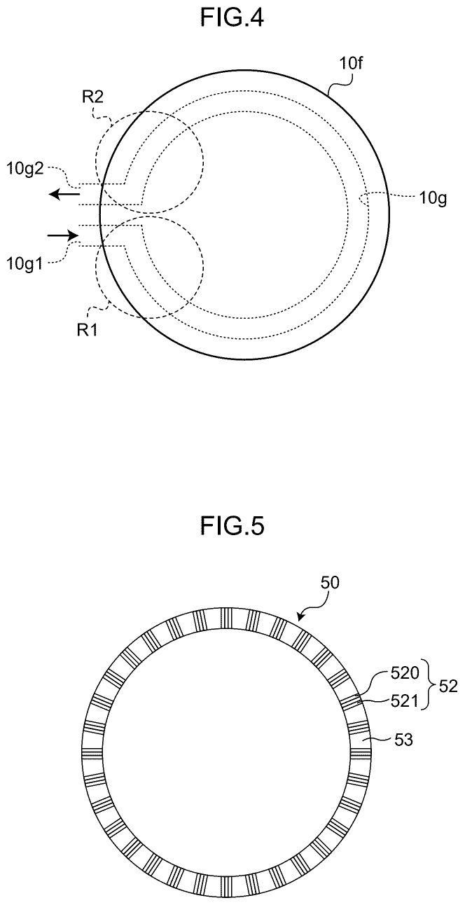

In addition, in the interior of the cooling plate 10f, for example, as shown in FIG. 4, a flow path 10g is disposed. FIG. 4 is a plan view showing an example of arrangement of the flow path 10g of the cooling plate 10f. In FIG. 4, the flow path 10g is shown by a broken line.

A heat transfer fluid whose temperature is controlled is supplied from a temperature control device such as a chiller unit into the cooling plate 10f. The heat transfer fluid supplied from the temperature control device flows into the flow path 10g from an inlet 10g1 and flows through the flow path 10g. The heat transfer fluid flowing through the flow path 10g performs heat exchange with the support member 10d via the cooling plate 10f and the ERG sheet 50, and is returned from an outlet 10g2 to the temperature control device.

Since the heat transfer fluid after performing heat exchange with the support member 10d flows out from the outlet 10g2, the temperature of the cooling plate 10f in a region R2 near the outlet 10g2 may be higher than the temperature of the cooling plate 10f in a region R1 near the inlet 10g1. In that case, even if the temperature of the heat transfer fluid is controlled, a temperature gradient occurs in the cooling plate 10f along the flow of the heat transfer fluid, and the temperature distribution of the cooling plate 10f becomes uneven. As a result, the temperature distribution of the support member 10d that performs heat exchange with the cooling plate 10f also becomes uneven.

Therefore, in the present embodiment, the ERG sheet 50 is disposed between the cooling plate 10f and the support member 10d. In addition, in the present embodiment, as shown in FIG. 5, for example, a plurality of electrode pairs 52 are disposed along a surface of the support member 10d on the cooling plate 10f side. By independently controlling the voltage applied to each electrode pair 52, the heat transfer coefficient between the cooling plate 10f and the support member 10d can be partially controlled. Then, for example, the voltage applied to each electrode pair 52 is controlled such that the heat transfer coefficient of the ER gel 51 in a portion where the temperature of the cooling plate 10f is relatively low is low, and the heat transfer coefficient in a portion where the temperature of the cooling plate 10f is relatively high is high. This can suppress unevenness in the temperature distribution of the support member 10d even when the temperature distribution of the cooling plate 10f is uneven.

In addition, in the plasma processing chamber 10, there are components that are heated to a predetermined temperature for the purpose of suppressing adhesion of deposition during plasma processing. Such components include those heated by plasma. Examples of such components include the deposition shield 10b and the member 10c and the like (see FIG. 2).

Therefore, in the present embodiment, the ERG sheet 50 is disposed between the support member 10d and the deposition shield 10b and between the support member 10d and the member 10c, and the heat transfer coefficient between the support member 10d and the deposition shield 10b and between the support member 10d and the member 10c is controlled. For example, when plasma processing is performed in the plasma processing chamber 10, the voltages applied to the electrode pairs 52 of the ERG sheet 50 are controlled such that the heat transfer coefficient between the support member 10d and the deposition shield 10b and between the support member 10d and the member 10c becomes small. This allows the deposition shield 10b and the member 10c to be heated by heat input from plasma without using heating means such as a heater.

In addition, temperature sensors are provided in the deposition shield 10b and the member 10c. Then, when the deposition shield 10b and the member 10c reach a predetermined temperature or higher, the voltages applied to the electrode pairs 52 of the ERG sheet 50 are controlled such that the heat transfer coefficient between the support member 10d and the deposition shield 10b and between the support member 10d and the member 10c becomes large. This can lower the temperature of the deposition shield 10b and the member 10c by heat exchange with the support member 10d.

In addition, when plasma processing is completed in the plasma processing chamber 10, the voltages applied to the electrode pairs 52 of the ERG sheet 50 are controlled such that the heat transfer coefficient between the support member 10d and the deposition shield 10b and between the support member 10d and the member 10c becomes large. This can quickly lower the temperature of the deposition shield 10b and the member 10c.

Note that, in the ERG sheet 50 disposed between the support member 10d and the deposition shield 10b and between the support member 10d and the member 10c, for example, as in the ERG sheet 50 shown in FIG. 5, a plurality of electrode pairs 52 are provided along an extending direction of the ERG sheet 50. This makes it possible to control the temperature distribution of the deposition shield 10b and the member 10c not only to a temperature distribution without unevenness but also to a temperature distribution with intentional unevenness. As another example, in the ERG sheet 50 disposed between the support member 10d and the deposition shield 10b and between the support member 10d and the member 10c, one electrode pair 52 may be disposed along the extending direction of the ERG sheet 50.

### Processing Method for Substrate W

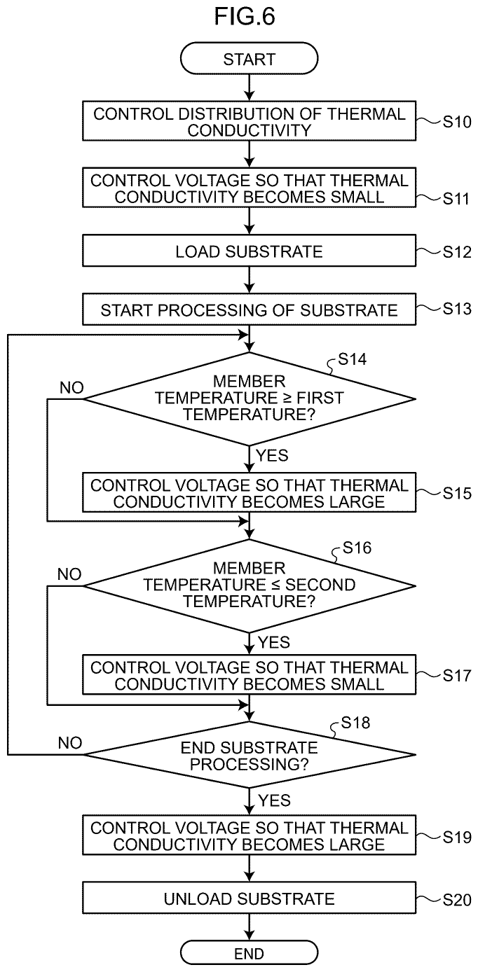

FIG. 6 is a flowchart showing an example of a processing method. Each step illustrated in FIG. 6 is realized by the control unit 2 controlling each part of the plasma processing apparatus 1. Note that, in the flowchart illustrated in FIG. 6, as an example, control of the ERG sheet 50 disposed between the cooling plate 10f and the support member 10d, between the support member 10d and the deposition shield 10b, and between the support member 10d and the member 10c is described.

First, a distribution of thermal conductivity of the ERG sheet 50 disposed between the cooling plate 10f and the support member 10d is controlled (step S10). Step S10 is an example of step a). In step S10, the voltage applied to each electrode pair 52 included in the ERG sheet 50 disposed between the cooling plate 10f and the support member 10d is individually controlled such that unevenness in the temperature distribution in the support member 10d becomes small.

Next, the thermal conductivity of the ERG sheet 50 disposed between the support member 10d and the deposition shield 10b and between the support member 10d and the member 10c is controlled to become small (step S11). In step S11, the voltages applied to the electrode pairs 52 of the ERG sheet 50 disposed between the support member 10d and the deposition shield 10b and between the support member 10d and the member 10c are controlled to be, for example, minimum (for example, 0V).

Next, the substrate W to be processed is loaded into the plasma processing chamber 10 (step S12). In step S12, a gate valve provided on the side wall 10a of the plasma processing chamber 10 is opened, and the substrate W is loaded into the plasma processing chamber 10 by a transfer robot. The substrate W is then transferred to lift pins protruding from the upper surface of the electrostatic chuck 1111. Then, the substrate W is placed on the upper surface of the electrostatic chuck 1111 by lowering the lift pins by driving an elevating mechanism. The elevating mechanism is controlled by the control unit 2.

Next, processing of the substrate W is started (step S13). Step S13 is an example of step b). In step S13, a processing gas is supplied from the gas supply unit 20 into the plasma processing chamber 10 via the shower head 13. Then, the interior of the plasma processing chamber 10 is adjusted to a predetermined pressure by the exhaust system 40. Then, by supplying RF power from the power supply 30 into the plasma processing chamber 10, the processing gas in the plasma processing chamber 10 is turned into plasma, and plasma is generated in the plasma processing chamber 10. Then, processing such as etching is performed on the substrate W by the plasma generated in the plasma processing chamber 10.

In addition, the member 10c and the deposition shield 10b are heated by the plasma generated in the plasma processing space 10s, and adhesion of deposition to the member 10c and the deposition shield 10b is suppressed. In step S11, the thermal conductivity of the ERG sheet 50 disposed between the support member 10d and the deposition shield 10b and between the support member 10d and the member 10c is controlled to become small. Therefore, the member 10c and the deposition shield 10b are efficiently heated by the plasma generated in the plasma processing space 10s.

Next, it is determined whether or not the temperature of a member in the plasma processing chamber 10 has reached a predetermined first temperature or higher (step S14). The members in the plasma processing chamber 10 are, for example, the deposition shield 10b and the member 10c. When the temperature of the member in the plasma processing chamber 10 is lower than the first temperature (step S14: No), the processing shown in step S16 is executed.

On the other hand, when the temperature of the member in the plasma processing chamber 10 has reached the first temperature or higher (step S14: Yes), the voltages applied to the electrode pairs 52 of the ERG sheet 50 are controlled such that the thermal conductivity of the ERG sheet 50 becomes large (step S15). Step S15 is an example of step d). This promotes heat exchange between, for example, the deposition shield 10b and the member 10c and the support member 10d, and lowers the temperature of the deposition shield 10b and the member 10c. This can prevent overheating of the deposition shield 10b and the member 10c.

Next, it is determined whether or not the temperature of the member in the plasma processing chamber 10 has become a predetermined second temperature or lower (step S16). The second temperature is a temperature lower than the first temperature. When the temperature of the member in the plasma processing chamber 10 is higher than the second temperature (step S16: No), the processing shown in step S18 is executed.

On the other hand, when the temperature of the member in the plasma processing chamber 10 has become the second temperature or lower (step S16: Yes), the voltages applied to the electrode pairs 52 of the ERG sheet 50 are controlled such that the thermal conductivity of the ERG sheet 50 becomes small (step S17). Step S17 is an example of step c). This suppresses heat exchange between, for example, the deposition shield 10b and the support member 10d, and between the member 10c and the support member 10d, and the temperature of the deposition shield 10b and the member 10c rises due to heat input from plasma. By the processing of steps S14 to S17, for example, the temperature of the deposition shield 10b and the member 10c can be maintained at a temperature between the first temperature and the second temperature.

Next, it is determined whether or not to end the processing of the substrate W (step S18). When the processing of the substrate W is not ended (step S18: No), the processing shown in step S14 is executed again.

On the other hand, when the processing of the substrate W is ended (step S18: Yes), control is performed such that the thermal conductivity between the support member 10d and the deposition shield 10b and between the support member 10d and the member 10c becomes large (step S19). Step S19 is an example of step e). In step S19, the voltages applied to the electrode pairs 52 of the ERG sheet 50 disposed between the support member 10d and the deposition shield 10b and between the support member 10d and the member 10c are controlled to be, for example, maximum. This can quickly lower the temperature of the deposition shield 10b and the member 10c.

Next, the substrate W is unloaded (step S20). In step S20, the substrate W is lifted by lift pins by driving an elevating mechanism. Then, a gate valve is opened, and the substrate W is unloaded from the plasma processing chamber 10 by a transfer robot. Then, the processing shown in this flowchart ends.

The embodiments have been described above. As described above, the processing apparatus (plasma processing apparatus 1) in the present embodiment includes a first member (cooling plate 10f), a second member (support member 10d), an ERG (Electro-Rheological Gel) sheet (ERG sheet 50) disposed between the first member and the second member, and a control unit (control unit 2). The ERG sheet has an ERG layer (ER gel 51), a plurality of electrode pairs (electrode pairs 52) each having two electrodes (electrode 520 and electrode 521), and a substrate (substrate 53) on which the plurality of electrode pairs are disposed. The control unit independently controls the thermal conductivity of the ERG layer in the vicinity of each of the plurality of electrode pairs by independently controlling voltages applied to each of the plurality of electrode pairs such that a temperature distribution of the first member or the second member becomes a predetermined temperature distribution due to heat exchange between the first member and the second member. This makes it possible to accurately control a temperature distribution of a member.

In addition, in the above-described embodiment, the electrode pair and the ERG layer are disposed on one surface of the substrate, the ERG layer in the ERG sheet is disposed on the first member side, and the substrate is disposed on the second member side. This can improve adhesion between the first member and the ERG sheet.

In addition, in the above-described embodiment, a sheet or an adhesive having high thermal conductivity and having electrical conductivity and elasticity is disposed between the substrate and the second member. This can improve adhesion between the second member and the substrate of the ERG sheet.

In addition, in the above-described embodiment, a temperature-controlled heat transfer fluid flows inside the first member, and the first member performs heat exchange with the second member via the ERG sheet. Even when unevenness occurs in the temperature distribution of the first member due to a temperature change of the heat transfer fluid, unevenness in the temperature distribution of the second member can be suppressed by independently controlling voltages applied to each of the plurality of electrode pairs.

In addition, the processing apparatus in the above-described embodiment further includes a processing container (plasma processing chamber 10) that performs processing on a wafer (substrate W) using plasma generated inside. The second member is heated by heat input from plasma in the processing container. The control unit controls the voltages applied to the electrode pairs such that the thermal conductivity of the ERG sheet becomes large when plasma is generated in the processing container and the temperature of the second member is a predetermined first temperature or higher. This can prevent overheating of the second member.

In addition, in the above-described embodiment, the control unit controls the voltages applied to the electrode pairs such that the thermal conductivity of the ERG sheet becomes small when the temperature of the second member becomes a second temperature lower than the first temperature or lower. This makes it possible to efficiently heat the second member by plasma generated in the processing container without providing a heater for heating the second member.

In addition, in the above-described embodiment, the control unit controls the voltages applied to the electrode pairs such that the thermal conductivity of the ERG sheet becomes large when generation of plasma in the processing container is completed. This can quickly lower the temperature of the second member.

In addition, the processing apparatus in the above-described embodiment further includes a shower head 13. The first member and the second member are provided around the shower head 13. This makes it possible to accurately control a temperature distribution of members around the shower head 13.

In addition, the above-described embodiment is a processing method in a processing apparatus. The processing apparatus includes a first member, a second member, an ERG (Electro-Rheological Gel) sheet disposed between the first member and the second member, a processing container that performs processing on a wafer using plasma generated inside, and a control unit, and the ERG sheet has an ERG layer, a plurality of electrode pairs each having two electrodes, and a substrate on which the plurality of electrode pairs are disposed. In the processing method, the control unit executes step a). In step a), the thermal conductivity of the ERG layer in the vicinity of each of the plurality of electrode pairs is independently controlled by independently controlling voltages applied to each of the plurality of electrode pairs such that a temperature distribution of the first member or the second member becomes a predetermined temperature distribution due to heat exchange between the first member and the second member. This makes it possible to accurately control a temperature distribution of a member.

In addition, in the above-described embodiment, a temperature-controlled heat transfer fluid flows inside the first member, and the second member performs heat exchange with the first member via the ERG sheet and is heated by heat input from plasma in the processing container. In addition, the control unit further executes step b) and step c). In step b), plasma is generated in the processing container. In step c), in a state where plasma is generated in the processing container, the voltages applied to the electrode pairs are controlled such that the thermal conductivity of the ERG sheet becomes small. This makes it possible to efficiently heat the second member by plasma generated in the processing container without providing a heater for heating the second member.

In addition, in the above-described embodiment, the control unit further executes step d). In step d), when the temperature of the second member reaches a predetermined temperature, the voltages applied to the electrode pairs are controlled such that the thermal conductivity of the ERG sheet becomes large. This can prevent overheating of the second member.

In addition, in the above-described embodiment, the control unit further executes step e). In step e), when generation of plasma in the processing container is completed, the voltages applied to the electrode pairs are controlled such that the thermal conductivity of the ERG sheet becomes large. This can quickly lower the temperature of the second member.

### Others

Note that the technology disclosed in the present application is not limited to the above-described embodiments, and various modifications are possible within the scope of the gist thereof.

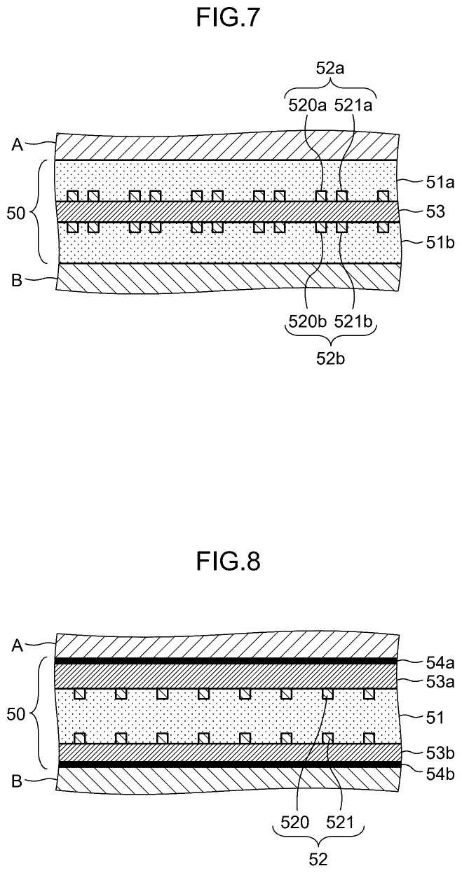

For example, in the ERG sheet 50 in the above-described embodiment, the ER gel 51 and the electrode pair 52 are disposed on one surface of the substrate 53, but the disclosed technology is not limited thereto. As another example, as shown in FIG. 7, for example, the ER gel 51 and the electrode pair 52 may be disposed on both surfaces of the substrate 53. FIG. 7 is a cross-sectional view showing another example of a structure of the ERG sheet 50.

The ERG sheet 50 illustrated in FIG. 7 has an ER gel 51a, an ER gel 51b, an electrode pair 52a, an electrode pair 52b, and a substrate 53. The electrode pair 52a includes an electrode 520a and an electrode 521a. The electrode pair 52b includes an electrode 520b and an electrode 521b. The ER gel 51a and the electrode pair 52a are disposed on one surface side of the substrate 53, and the ER gel 51b and the electrode pair 52b are disposed on the other surface side of the substrate 53. The electrode pair 52a is an example of a first electrode pair, and the electrode pair 52b is an example of a second electrode pair. In addition, the ER gel 51a is an example of a first ERG layer, and the ER gel 51b is an example of a second ERG layer.

In addition, the ERG sheet 50 may have a structure in which the ER gel 51 is sandwiched between two substrates 53, as shown in FIG. 8, for example. FIG. 8 is a cross-sectional view showing another example of a structure of the ERG sheet 50. The ERG sheet 50 illustrated in FIG. 8 has an ER gel 51, an electrode pair 52, a substrate 53a, a substrate 53b, a thermally conductive sheet 54a, and a thermally conductive sheet 54b. The ER gel 51 is disposed between the substrate 53a and the substrate 53b. The electrode pair 52 includes an electrode 520 and an electrode 521, the electrode 520 is disposed on the substrate 53a, and the electrode 521 is disposed on the substrate 53b. In the example of FIG. 8, one electrode included in the electrode pair 52 is disposed on a surface of the substrate 53a on the ER gel 51 side, and the other electrode included in each electrode pair 52 is disposed on a surface of the substrate 53b on the ER gel 51 side.

A thermally conductive sheet 54a is disposed between the member A and the substrate 53a, and a thermally conductive sheet 54b is disposed between the member B and the substrate 53b. Note that, instead of the thermally conductive sheet 54a and the thermally conductive sheet 54b, an adhesive having high thermal conductivity may be disposed. The substrate 53a is an example of a first substrate, and the substrate 53b is an example of a second substrate.

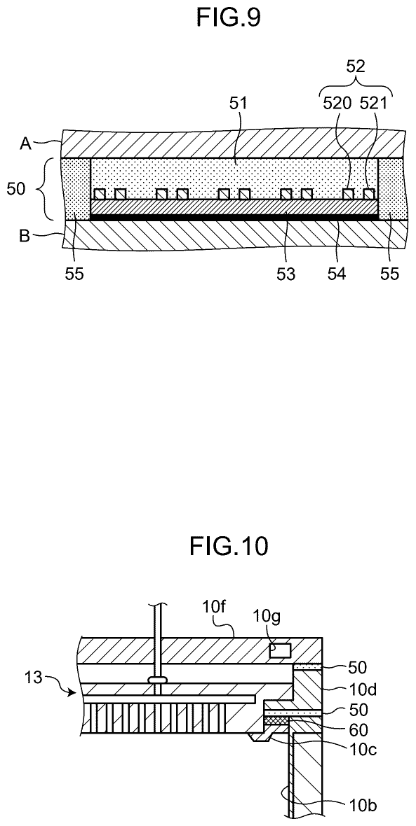

In addition, in the ERG sheet 50, at an end of the ER gel 51, for example, as shown in FIG. 9, a low thermal conductivity member 55 may be disposed. The low thermal conductivity member 55 is formed of, for example, heat-resistant rubber (based on organic polymers such as natural rubber or synthetic rubber), resin (e.g., a polymer compound such as epoxy resin), ceramic (alumina, zirconia), quartz, SUS (Steel Use Stainless) material, Hastelloy (registered trademark), titanium, zircaloy, or the like. By disposing the low thermal conductivity member 55 at the end of the ER gel 51, the ER gel 51 is prevented from leaking to the outside of the ERG sheet 50. In addition, the ER gel 51 can be prevented from being exposed to plasma, gas, or the like, and deterioration of the ER gel 51 can be suppressed.

In addition, between the ERG sheet 50 and the member 10c, for example, as shown in FIG. 10, a heater 60 for heating the deposition shield 10b and the member 10c may be provided. FIG. 10 is an enlarged cross-sectional view showing another example of a detailed structure near an outer periphery of the shower head 13. This makes it possible to heat the temperature of the deposition shield 10b and the member 10c to a predetermined temperature before plasma is generated in the plasma processing chamber 10. Note that, after plasma is generated in the plasma processing chamber 10, power supply to the heater 60 may be stopped.

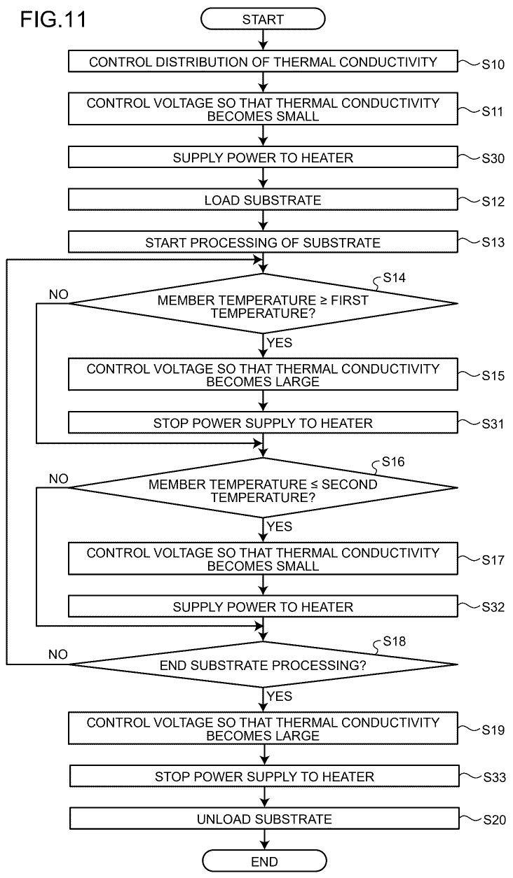

FIG. 11 is a flowchart showing another example of a processing method. The processing illustrated in FIG. 11 is performed by the plasma processing apparatus 1 having the structure illustrated in FIG. 10. Note that, except for the points described below, in FIG. 11, processing to which the same reference numerals as in FIG. 6 are assigned is the same as the processing described in FIG. 6, and thus description thereof is omitted.

In step S11, after the thermal conductivity of the ERG sheet 50 disposed between the support member 10d and the deposition shield 10b and between the support member 10d and the member 10c is controlled to become small, power is supplied to the heater 60 (step S30). This makes it possible to quickly heat the temperature of the deposition shield 10b and the member 10c to a predetermined temperature.

In addition, in step S15, after the thermal conductivity of the ERG sheet 50 disposed between the support member 10d and the deposition shield 10b and between the support member 10d and the member 10c is controlled to become large, power supply to the heater 60 is stopped (step S31). This can quickly lower the temperature of the deposition shield 10b and the member 10c.

In addition, in step S17, after the thermal conductivity of the ERG sheet 50 disposed between the support member 10d and the deposition shield 10b and between the support member 10d and the member 10c is controlled to become small, power is supplied to the heater 60 again (step S32). This makes it possible to quickly raise the temperature of the deposition shield 10b and the member 10c. Note that, in a state where plasma is generated in the plasma processing chamber 10, the deposition shield 10b and the member 10c are heated by the plasma and, in such a case, power is not supplied to the heater 60 in step S32.

In addition, in step S19, after the thermal conductivity of the ERG sheet 50 disposed between the support member 10d and the deposition shield 10b and between the support member 10d and the member 10c is controlled to become large, power supply to the heater 60 is stopped (step S33). This can quickly lower the temperature of the deposition shield 10b and the member 10c.

In addition, in the above-described embodiment, the ERG sheet 50 is disposed between the cooling plate 10f and the support member 10d, between the support member 10d and the deposition shield 10b, and between the support member 10d and the member 10c, but the disclosed technology is not limited thereto. The ERG sheet 50 may be disposed between other two members, such as between the electrostatic chuck 1111 and the base 1110 or between the electrostatic chuck 1111 and the ring assembly 112, as long as there is heat transfer between the two members.

In addition, in the above-described embodiment, the plasma processing apparatus 1 that performs processing using capacitively coupled plasma (CCP) has been described as an example of a plasma source, but the plasma source is not limited thereto. Examples of plasma sources other than capacitively coupled plasma include inductively coupled plasma (ICP), microwave-excited surface wave plasma (SWP), electron cyclotron resonance plasma (ECP), helicon wave-excited plasma (HWP), and the like.

The embodiments disclosed herein are illustrative and not restrictive. The heat transfer coefficient referred to in the examples of the present application is sometimes called a contact heat transfer coefficient. The above-described embodiments may be implemented in various forms. In addition, the above embodiments may be omitted, replaced, or changed in various forms without departing from the scope and spirit of the appended claims.

According to various aspects and embodiments of the present disclosure, a temperature distribution of a member can be accurately controlled.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

In addition, the following supplementary notes are further disclosed regarding the above embodiments.

### (Supplementary Note 1)

A processing apparatus comprising:
a first member;
a second member;
an ERG (Electro-Rheological Gel) sheet disposed between the first member and the second member; and
control circuitry,
wherein the ERG sheet includes:
an ERG layer;
a plurality of electrode pairs each having two electrodes; and
a substrate on which the plurality of electrode pairs are disposed,
wherein the control circuitry independently control thermal conductivity of the ERG layer in the vicinity of each of the plurality of electrode pairs by independently controlling voltages applied to each of the plurality of electrode pairs such that a temperature distribution of the first member or the second member becomes a predetermined temperature distribution due to heat exchange between the first member and the second member.

### (Supplementary Note 2)

The processing apparatus according to Supplementary Note 1,
wherein the electrode pair and the ERG layer are disposed on one surface of the substrate, the ERG layer in the ERG sheet is disposed on the first member side, and the substrate is disposed on the second member side.

### (Supplementary Note 3)

The processing apparatus according to Supplementary Note 2, wherein a sheet or an adhesive having electrical conductivity and elasticity is disposed between the substrate and the second member.

### (Supplementary Note 4)

The processing apparatus according to Supplementary Note 1,
wherein the electrode pair includes a first electrode pair and a second electrode pair,
the ERG layer includes a first ERG layer and a second ERG layer,
the first electrode pair and the first ERG layer are disposed on one surface of the substrate,
the second electrode pair and the second ERG layer are disposed on the other surface of the substrate, and
the first ERG layer is disposed on the first member side, and the second ERG layer is disposed on the second member side.

### (Supplementary Note 5)

The processing apparatus according to Supplementary Note 1,
wherein the substrate includes a first substrate and a second substrate,
the ERG layer is disposed between the first substrate and the second substrate,
one electrode included in each of the electrode pairs is disposed on a surface of the first substrate on the ERG layer side, and
the other electrode included in each of the electrode pairs is disposed on a surface of the second substrate on the ERG layer side.

### (Supplementary Note 6)

The processing apparatus according to Supplementary Note 5,
wherein the first substrate is disposed on the first member side,
the second substrate is disposed on the second member side, and
a sheet or an adhesive having electrical conductivity and elasticity is disposed between the first substrate and the first member and between the second substrate and the second member.

### (Supplementary Note 7)

The processing apparatus according to any one of Supplementary Note 1 to 6,
wherein a temperature-controlled heat transfer fluid flows inside the first member, and
the first member performs heat exchange with the second member via the ERG sheet.

### (Supplementary Note 8)

The processing apparatus according to Supplementary Note 7, further comprising
a processing container that performs processing on a wafer using plasma generated inside,
wherein the second member is heated by heat input from plasma in the processing container, and
the control circuitry control the voltages applied to the electrode pairs such that the thermal conductivity of the ERG sheet becomes large when plasma is generated in the processing container and the temperature of the second member is a predetermined first temperature or higher.

### (Supplementary Note 9)

The processing apparatus according to Supplementary Note 8, wherein the control circuitry control the voltages applied to the electrode pairs such that the thermal conductivity of the ERG sheet becomes small when the temperature of the second member becomes a second temperature that is lower than the first temperature or lower.

### (Supplementary Note 10)

The processing apparatus according to Supplementary Note 8 or 9, wherein the control circuitry control the voltages applied to the electrode pairs such that the thermal conductivity of the ERG sheet becomes large when generation of plasma in the processing container is completed.

### (Supplementary Note 11)

The processing apparatus according to any one of Supplementary Note 8 to 10,
wherein a heater is embedded in the second member, and
the control circuitry control to supply power to the heater when controlling the voltages applied to the electrode pairs such that the thermal conductivity of the ERG sheet becomes small.

### (Supplementary Note 12)

The processing apparatus according to any one of Supplementary Note 1 to 11, further comprising a shower head,
wherein the first member and the second member are provided around the shower head.

### (Supplementary Note 13)

A processing method in a processing apparatus including a first member, a second member, an ERG (Electro-Adhesive Gel) sheet disposed between the first member and the second member, a processing container that performs processing on a wafer using plasma generated inside, and control circuitry,
in which the ERG sheet includes an ERG layer, a plurality of electrode pairs each having two electrodes, and a substrate on which the plurality of electrode pairs are disposed,
the processing method comprising:
the control circuitry executing:
a) independently controlling thermal conductivity of the ERG layer in the vicinity of each of the plurality of electrode pairs by independently controlling voltages applied to each of the plurality of electrode pairs such that a temperature distribution of the first member or the second member becomes a predetermined temperature distribution due to heat exchange between the first member and the second member.

### (Supplementary Note 14)

The processing method according to Supplementary Note 13,
wherein a temperature-controlled heat transfer fluid flows inside the first member,
the second member performs heat exchange with the first member via the ERG sheet and is heated by heat input from plasma in the processing container, and
the control circuitry further execute:
b) generating plasma in the processing container; and
c) controlling the voltages applied to the electrode pairs such that the thermal conductivity of the ERG sheet becomes small in a state where plasma is generated in the processing container.

### (Supplementary Note 15)

The processing method according to Supplementary Note 14,
wherein the control circuitry further execute:
d) controlling the voltages applied to the electrode pairs such that the thermal conductivity of the ERG sheet becomes large when the temperature of the second member reaches a predetermined temperature.

### (Supplementary Note 16)

The processing method according to Supplementary Note 14 or 15,
wherein the control circuitry further execute:
e) controlling the voltages applied to the electrode pairs such that the thermal conductivity of the ERG sheet becomes large when generation of plasma in the processing container is completed.

What is claimed is:

1. A processing apparatus, comprising:
a first member;
a second member;
an ERG (Electro-Rheological Gel) sheet disposed between the first member and the second member, the ERG sheet including:
an ERG layer;
a plurality of electrode pairs each having two electrodes; and
a substrate on which the plurality of electrode pairs are disposed; and
control circuitry configured to control thermal conductivity of the ERG layer, for each of the plurality of electrode pairs, by independently controlling voltages applied to each of the plurality of electrode pairs such that a temperature distribution of the first member or the second member becomes a predetermined temperature distribution due to heat exchange between the first member and the second member.

2. The processing apparatus according to claim 1, wherein an electrode pair and a corresponding ERG layer are disposed on one surface of the substrate, the ERG layer in the ERG sheet is disposed on a side of the first member, and the substrate is disposed on a side of the second member.

3. The processing apparatus according to claim 2, wherein a sheet or an adhesive having electrical conductivity and elasticity is disposed between the substrate and the second member.

4. The processing apparatus according to claim 1, wherein
the plurality of electrode pairs includes a first electrode pair and a second electrode pair,
the ERG layer includes a first ERG layer and a second ERG layer,
the first electrode pair and the first ERG layer are disposed on one surface of the substrate,
the second electrode pair and the second ERG layer are disposed on the other surface of the substrate, and
the first ERG layer is disposed on a side of the first member, and the second ERG layer is disposed on a side of the second member.

5. The processing apparatus according to claim 1, wherein
the substrate includes a first substrate and a second substrate,
the ERG layer is disposed between the first substrate and the second substrate,
one electrode included in each of the electrode pairs is disposed on a surface of the first substrate on the ERG layer side, and
the other electrode included in each of the electrode pairs is disposed on a surface of the second substrate on the ERG layer side.

6. The processing apparatus according to claim 5, wherein
the first substrate is disposed on a side of the side,
the second substrate is disposed on a side of the member side, and
a sheet or an adhesive having electrical conductivity and elasticity is disposed between the first substrate and the first member and between the second substrate and the second member.

7. The processing apparatus according to claim 1, wherein
a temperature-controlled heat transfer fluid flows inside the first member, and
the first member performs heat exchange with the second member via the ERG sheet.

8. The processing apparatus according to claim 7, further comprising:
a processing container that performs processing on a wafer using plasma generated inside, wherein
the second member is heated by heat input from plasma in the processing container, and
the control circuitry controls the voltages applied to the electrode pairs such that the thermal conductivity of the ERG sheet becomes large when plasma is generated in the processing container and the temperature of the second member is a predetermined first temperature or higher.

9. The processing apparatus according to claim 8, wherein the control circuitry controls the voltages applied to the electrode pairs such that the thermal conductivity of the ERG sheet decreases when the temperature of the second member becomes lower than the first temperature.

10. The processing apparatus according to claim 8, wherein the control circuitry controls the voltages applied to the electrode pairs such that the thermal conductivity of the ERG sheet increases when generation of plasma in the processing container is completed.

11. The processing apparatus according to claim 8, wherein
a heater is embedded in the second member, and
the control circuitry is configured to control to supply power to the heater when controlling the voltages applied to the electrode pairs such that the thermal conductivity of the ERG sheet becomes small.

12. The processing apparatus according to claim 1, further comprising a shower head, wherein the first member and the second member are provided around the shower head.

13. A processing method in a processing apparatus including a first member, a second member, an ERG (Electro-Adhesive Gel) sheet disposed between the first member and the second member, a processing container that performs processing on a wafer using plasma generated inside, and control circuitry, wherein the ERG sheet includes an ERG layer, a plurality of electrode pairs each having two electrodes, and a substrate on which the plurality of electrode pairs are disposed, the processing method comprising:
a) controlling thermal conductivity of the ERG layer, for each of the plurality of electrode pairs, by independently controlling voltages applied to each of the plurality of electrode pairs such that a temperature distribution of the first member or the second member becomes a predetermined temperature distribution due to heat exchange between the first member and the second member.

14. The processing method according to claim 13, wherein
a temperature-controlled heat transfer fluid flows inside the first member,
the second member performs heat exchange with the first member via the ERG sheet and is heated by heat input from plasma in the processing container, and
the processing method further comprises:
b) generating plasma in the processing container; and
c) controlling the voltages applied to the electrode pairs such that the thermal conductivity of the ERG sheet decreases when plasma is generated in the processing container.

15. The processing method according to claim 14, further comprising:
d) controlling the voltages applied to the electrode pairs such that the thermal conductivity of the ERG sheet increases when the temperature of the second member reaches a predetermined temperature.

16. The processing method according to claim 14, further comprising:
e) controlling the voltages applied to the electrode pairs such that the thermal conductivity of the ERG sheet increases when generation of plasma in the processing container is completed.

17. The processing method according to claim 13, wherein an electrode pair and a corresponding ERG layer are disposed on one surface of the substrate, the ERG layer in the ERG sheet is disposed on a side of the first member, and the substrate is disposed on a side of the second member.

18. The processing method according to claim 17, wherein a sheet or an adhesive having electrical conductivity and elasticity is disposed between the substrate and the second member.

19. The processing method according to claim 13, wherein
the plurality of electrode pairs includes a first electrode pair and a second electrode pair,
the ERG layer includes a first ERG layer and a second ERG layer,
the first electrode pair and the first ERG layer are disposed on one surface of the substrate,
the second electrode pair and the second ERG layer are disposed on the other surface of the substrate, and
the first ERG layer is disposed on a side of the first member, and the second ERG layer is disposed on a side of the second member.

20. A processing apparatus, comprising:
a plate;
a support;
an ERG (Electro-Rheological Gel) sheet disposed between the plate and the support, the ERG sheet including:
an ERG layer;
a plurality of electrode pairs each having two electrodes; and
a substrate on which the plurality of electrode pairs are disposed; and
control circuitry configured to control thermal conductivity of the ERG layer, for each of the plurality of electrode pairs, by independently controlling voltages applied to each of the plurality of electrode pairs such that a temperature distribution of the plate or the support becomes a predetermined temperature distribution due to heat exchange between the plate and the support.
